(19) United States
(12) Patent Application Publication
(10) Pub. No.: US 2026/0320242 A1
(43) Pub. Date: Oct. 15, 2026

(54) METHOD AND SYSTEM FOR OPTIMIZING LOAD INTERCONNECTION CAPACITY THROUGH SELECTIVE CONTINGENCY MITIGATION IN POWER SYSTEMS

(71) Applicant: GRIDCARE, Inc., Redwood City, CA (US)

(72) Inventors: Ram Rajagopal, Redwood City, CA (US); Liang Min, Redwood City, CA (US); Adam Wigington, Redwood City, CA (US); Songzhe Zhu, Redwood City, CA (US); Aashish Pasupuleti, Redwood City, CA (US); Amit Narayan, Redwood City, CA (US)

(73) Assignee: GRIDCARE, Inc., Redwood City, CA (US)

(21) Appl. No.: 19/646,396

(22) Filed: Apr. 13, 2026

Related U.S. Application Data
(60) Provisional application No. 63/787,685, filed on Apr. 11, 2025.

(51) Int. Cl. G06F 30/18

(52) U.S. Cl. CPC G06F 30/18

(57) ABSTRACT

This disclosure provides methods and systems for determining interconnection capacity by selectively identifying and mitigating a minimal subset of contingency scenarios that would otherwise limit load interconnection at a Point of Interconnection (POI). Rather than assuming all contingencies must be satisfied without mitigation, the disclosure identifies which scenarios can be mitigated using a cost-effective strategy, how to incorporate them into the system planning process, and which can be left unmitigated while still satisfying a system-wide reliability target.

### CROSS-REFERENCE TO RELATED APPLICATIONS

This application claims the benefit of U.S. Provisional Application No. 63/787,685, filed Mar. 11, 2025, which is hereby incorporated by reference herein in its entirety, including but not limited to those portions that specifically appear hereinafter, the incorporation by reference being made with the following exception: In the event that any portion of the above-referenced provisional application is inconsistent with this application, this application supersedes said above-referenced provisional application.

### BACKGROUND

### 1. Technical Field

This disclosure relates to electrical power systems and, more specifically, to methods to determine and enable the interconnection of large electrical loads to the power grid through optimization-based contingency analysis and mitigation.

### 2. Background

The growing demand for grid interconnections from large and flexible electrical loads—including data centers, industrial operations, hydrogen electrolyzers, and electric vehicle fleets—places pressure on existing grid infrastructure that is already constrained as expensive and timely capital projects are difficult to get approved along with long supply chain lead times. Interconnecting these loads reliably on the transmission system requires a detailed analysis of system contingencies as defined by the NERC (“North American Electric Reliability Corporation”) Transmission Planning (TPL) 001-5 standards (P0 to P7, including N-1 and N-2 scenarios) under single most constrained period (typically a high summer peak case). NERC standards, which define electrical system performance criteria include categories P0-normal system; P1 (Single-element loss), P2 (Single element fault), P3 (Generator Outage and system adjustment); P4 (Multiple element fault); P5 (Multiple element delayed fault), P6 (Transmission Outage and system adjustment), and P7 (Multiple element loss in a common structure).

Traditionally, transmission operators use a conservative approach to study each individual customer request on an as needed basis. For each request, assess all contingencies under the worst-case load conditions to determine the injection under each contingency. The minimum of these values dictates the maximum interconnection capacity, even if the majority of contingencies are low probability or only bind under rare conditions. This practice leads to under-utilization of available transmission capacity and delays interconnection timelines. In addition, large load customers or developers do not know the capacity available at any particular location before making a request, so they can make many speculative requests leading to significant inefficiencies into the process.

While prior art systems (e.g., U.S. Pat. No. 10,229,376B2) address real-time contingency response during grid operations, they do not address the fundamental problem of determining interconnection capacity during the planning phase. The present disclosure uniquely combines: (i) optimization-based selection of which contingencies to mitigate; (ii) generation of contractual specifications embedding mitigation obligations; and (iii) time-varying (hourly and seasonal) mitigation schedules that enable higher capacity interconnections while maintaining reliability. This planning-focused approach is fundamentally distinct from operational contingency response systems.

Although mitigation technologies, such as battery storage, demand response, and backup generation, can offer flexible response during emergencies, they are rarely explicitly integrated into interconnection capacity assessments. Moreover, current procedures do not support time-varying mitigation (e.g., seasonal, hourly), nor do they leverage probabilistic or optimization-based methods to prioritize which contingencies must be mitigated.

Recent advances in optimization, probabilistic risk modeling, smart contract enforcement, and real-time monitoring systems make it feasible to modernize this process. This disclosure provides a structured, optimization-driven approach to selective contingency mitigation, allowing higher capacity interconnections without compromising grid reliability.

### SUMMARY

This disclosure provides methods and systems for determining interconnection capacity by selectively identifying and mitigating a minimal subset of contingency scenarios that would otherwise limit load interconnection at a Point of Interconnection (POI). Rather than assuming all contingencies must be satisfied without mitigation, the disclosure identifies which scenarios can be mitigated using a cost-effective strategy, how to incorporate them into the system planning process, and which can be left unmitigated while still satisfying a system-wide reliability target.

The mitigation strategy may include load reduction, dispatch of energy storage systems, activation of backup generation, or deployment of grid-enhancing technologies (GETs). These mitigations can be activated based on detection of a triggering contingency, and may be scheduled on an hourly or seasonal basis.

A mathematical optimization model is used to select the optimal subset of contingencies to mitigate, minimizing cost while ensuring that the desired interconnection capacity is feasible under all relevant operating conditions. The model supports mixed-integer formulations, probabilistic thresholds, and multi-objective weighting (e.g., combining cost, risk, and impact).

The system also includes support for contract generation, detailing each contingency, required mitigation actions, and response time. A monitoring and enforcement module ensures compliance with the agreed-upon mitigation terms and enables smart contract implementation if desired.

In addition, the system supports mitigation of double contingencies (P3 and P6 categories in the NERC TPL 001-5 standard) through staged logic, wherein mitigation is only activated upon detection of the first fault in the event sequence. This enables more efficient response while preserving system integrity and is allowed under the NERC standard through “system adjustments.”

In one embodiment, a system may model potential new load connections using the techniques described herein to identify certain parameters which must be met to provide electrical service for a particular project, facility, or other need. The model may simulate a current electrical grid infrastructure and simulate an addition to the electrical load for a proposed project (e.g., an electrical provisioning simulation). Based on the simulated load, the system may test for grid infrastructure weaknesses or supply issues and provide parameters to be addressed in order to service the requested project, facility, or other need. Methods for implementing this system are also disclosed.

In another embodiment, a system may monitor electrical use by the project, facility, or other need to ensure compliance with the identified parameters. The system may both monitor the project, facility, or other need for compliance with the identified parameters, and automatically adjust electrical provisioning when the identified parameters are outside an acceptable level. Methods for implementing this system are also disclosed.

### BRIEF DESCRIPTION OF THE DRAWINGS

The accompanying drawings illustrate embodiments of systems and methods for optimizing load interconnection capacity through selective contingency mitigation in power systems. The illustrated embodiments are exemplary and do not limit the scope of the disclosure.

FIG. 1 illustrates a systemic view of a power system which experiences optimization of load interconnection capacity and selective contingency mitigation.

FIG. 2 illustrates an exemplary method for optimizing load interconnection capacity and selective contingency mitigation.

FIG. 3 illustrates an exemplary user interface for a power system which experiences optimization of load interconnection capacity and selective contingency mitigation.

FIG. 4 illustrates an exemplary view of a power system with mitigated and unmitigated power system contingencies.

FIG. 5 illustrates a method for mitigating a detected contingency.

FIG. 6 illustrates a method for simulating a load connection and analyzing risk probabilities.

### DETAILED DESCRIPTION OF PREFERRED EMBODIMENTS

In the following description, for purposes of explanation and not limitation, specific techniques and embodiments are set forth, such as particular techniques and configurations, in order to provide a thorough understanding of the device disclosed herein. While the techniques and embodiments will primarily be described in context with the accompanying drawings, those skilled in the art will further appreciate that the techniques and embodiments may also be practiced in other similar devices.

Reference will now be made in detail to the exemplary embodiments, examples of which are illustrated in the accompanying drawings. Wherever possible, the same reference numbers are used throughout the drawings to refer to the same or like parts. It is further noted that elements disclosed with respect to particular embodiments are not restricted to only those embodiments in which they are described. For example, an element described in reference to one embodiment or figure, may be alternatively included in another embodiment or figure regardless of whether or not those elements are shown or described in another embodiment or figure. In other words, elements in the figures may be interchangeable between various embodiments disclosed herein, whether shown or not.

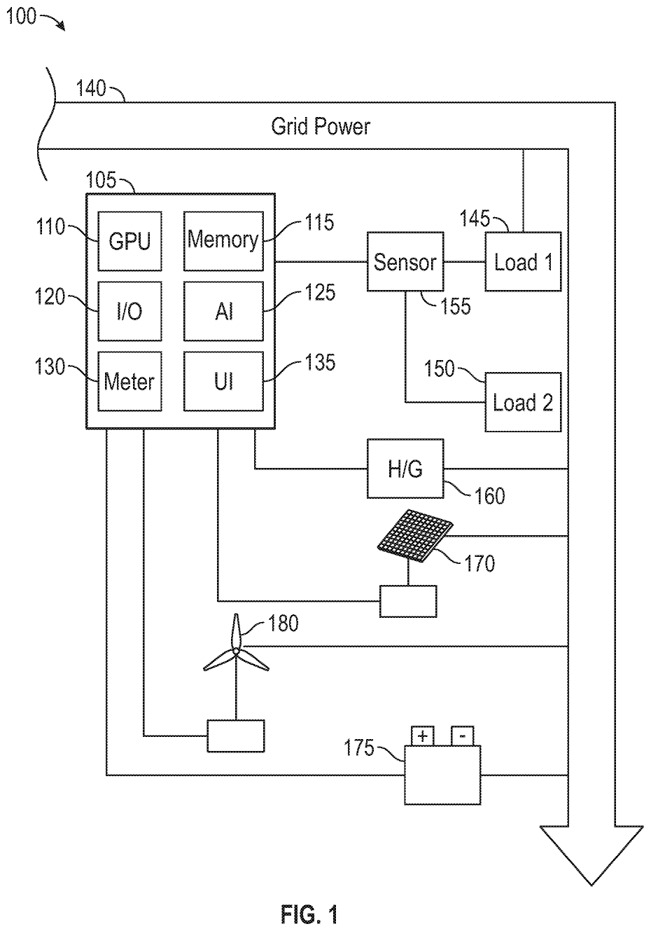

FIG. 1 illustrates a system 100 which experiences optimization of load interconnection capacity and selective contingency mitigation. System 100 may include a computer device 105. Computer device 105 may be implemented as one or a plurality of desktop computers, laptop computers, tablets, game consoles, personal computers, notebook computers, smart phones, smart watches, personal entertainment devices, sever computing devices, cloud computing devices, and any other electrical computing device with access to processing power sufficient to interact with computer device 105. Computer device 105 may include may further include software and hardware modules, sequences of instructions, routines, data structures, display interfaces, and other types of structures that execute processor operations. Further, hardware components may include a combination of Central Processing Units (“CPUs”), general processing units (“GPUs”) buses, volatile and non-volatile memory devices, storage units, non-transitory computer-readable storage media, data processors, processing devices, control devices transmitters, receivers, antennas, transceivers, input devices, output devices, network interface devices, and other types of components that are apparent to those skilled in the art. In particular, computer device 105 includes a GPU 110 which executes computer instructions stored in memory device 115 to perform methods described herein. Memory device 115 may incorporate different kinds and types of memory, which include volatile and non-volatile memory devices. Computer device 105 may further receive information from various sources, including a user, via an input/output (“I/O”) module. Computer device 125 may further include an artificial intelligence engine 125 which may create learning models and execute machine learning techniques, such as receiving data about historical information and using the historical information to predict future information. Artificial intelligence engine 125 may generate new information or provide optimization suggestions for individual POI interconnect requests, as will be discussed below. Computer device 105 may further provide a user interface 135, which will be discussed below, which allows one or more users to interact with computer device 105, particularly when meter 130 detects a contingency condition, as will be discussed below.

System 100 further illustrates grid power 140 which may be a power supply which serves a general population. For example, individual entities or municipalities, states, regions, or other jurisdictional entities may generate power at a power station. Power generally is generated by water turbines installed in dams in rivers or steam turbines with various heat sources that include nuclear, coal, or other similar fuels. As water or steam flows over the turbines, electricity is created by the power generating entity and sold to the general public for use as “grid power,” shown as grid power 140. One limitation of grid power is electrical generation capacity. For example, a hydroelectric dam with 8 turbines run 24 hours a day can produce a certain amount of electricity as a maximum output, and frequently less. If more electricity is demanded that what is available, the power grid can suffer failures. Similarly, another limitation of grid power is demand. Since less electricity is generally required at night, generating electricity at night is useless unless the energy can be stored in a battery system.

Computer device 105 alleviates both the capacity issue and the demand issue by managing load interconnects, such as load 1 145 and load 2 150. in terms of using what power is available when it is available, as will be discussed below. For example, load 1 145 may be an artificial intelligence data center which has significant power needs that may be the subject of a request for a new POI. Computer device 105 may simulate the new POI based on current power grid obligations to assess whether or not a power grid can handle the additional requested capacity of grid power 140 and optimize power allocations. In other words, power requested by the data center may be supplied at all times, at some times, or the request may be denied. Computer device 105 may assess what power constraints may be placed upon the request for grid power. Load 2 150 may be a second new interconnect for a charging station for a fleet of delivery vehicles which may request power for charging vehicles at a generally high capacity but at a certain time of day. Computer device 105 may further assess what power constraints may be placed on the request for grid power 140 based on specific power needs of load 2 150. For example, if load 2 150 is charging a fleet of electric vehicles, computer device 105 may identify specific timeframes for when to charge the electric vehicles (or at which grid power 140 will be provisioned) based on how much electricity is requested for load 2, 150.

Computer 105 may have access to one or more sensors 155 which detect energy usage and ensure that power is being supplied to load 1 145 and load 2 150 at agreed upon capacity and timing. In the event that load 1 145 or load 2 150 requires additional capacity at a certain time, computer 105 may have access to one or more GETs, such as a hydrogen electrolyzer/generator 160, solar panel 170, battery storage 175, and wind power 180, to provide additional electricity to grid power 140 for a certain timeframe. When load 1 145 or load 2 150 uses more capacity than available, called an “overage,” a contingency is provided as an additional supply of electricity from one or more GETs. When the one or more GETs supplies electricity, the overage may be mitigated.

Inputs and setup may be part of a generated by computer device 105 simulation system using the disclosed methods to simulate a new potential electrical load being connected to an electrical supply grid. The system may implement methods by processor 110 in one or more devices to address the following: capacity request at a specific Point of Interconnection (POI) (e.g., load 1, 145 and load 2 15); a contingency library (e.g., NERC TPL 001-05 categories P0 to P7); grid network elements, topology configuration, and operational constraints and controls (e.g., GETs); historical or estimated contingency probability data; and historical and forecast load data.

Each contingency scenario is simulated by computer device 105 under the proposed interconnection capacity to determine whether the system remains within acceptable power limits. Contingencies may include potential points of failure for the electrical supply grid. For steady-state analysis (power flow studies) the simulation must converge to a feasible solution. If it does converge, the solution state is checked for thermal and voltage magnitude violations. Additional attributes, such as expected load reductions and historical likelihood of occurrence, are calculated or retrieved.

Computer device 105 may store an optimization model in memory 115. The optimization model is formulated to select the smallest or least-cost subset of contingencies that require mitigation in order to satisfy the interconnection request in a provisioning simulation. The objective function may minimize one or more of the following: number of mitigated contingencies; total cost of mitigation; total expected load reduction; and weighted probability of occurrence across selected contingencies. Multi-objective formulations can be employed to balance these trade-offs, with user-defined weights reflecting system preferences or regulatory constraints. For each selected contingency, a mitigation strategy is assigned, which may include load reduction (e.g., demand response, automatic load reduction control schemes), dispatch of co-located or nearby battery storage systems; activation of on-site or contracted backup generation; adjustment or deployment of GETs such as FACTS devices, dynamic line ratings, or topology control, and line and other equipment upgrades. FACTS devices include static VAR compensators (SVCs), static synchronous compensators (STATCOMs), thyristor-controlled phase-shifting transformers (TCPSTs); dynamic line rating (DLR) systems; topology optimization controllers; and grid-forming inverters capable of providing synthetic inertia and voltage support during contingency events.

A contractual specification is generated by computing device 105 for detailing system parameters required for provisioning the electrical load from the electrical grid The parameters may include elements such as the subset of contingencies requiring mitigation; the specific response required (e.g., MW reduced or injected); response times and duration, and penalties or enforcement mechanisms. In other words, as part of a POI request or an electrical provisioning request, computing device 105 may identify terms for providing the requested electrical supply based on the foregoing parameters. If load 1, 145 uses too much electricity at a particular time in a manner that violates the POI request or provisioning agreement, computer device 105 may be informed by sensor 155 that a breach has taken place and ensure that the entity associated with load 1 appropriately mitigates the demand in a specific amount of time, for a specific amount of load, and agreed penalties for the breach.

Computer device 105 may monitor an electrical load that is provisioned by the electrical power grid to detect triggering contingencies in real-time based on identified parameters; measure mitigation resource performance, verify compliance with contractual obligations, and report violations and trigger enforcement mechanisms.

Computer device 105 may, based on new POI requests or load provisioning requests, generate formal contracts that specify parameters for each contingency that must be mitigated, the required magnitude of response (in MW), the activation delay and response duration, and enforcement terms (e.g., penalties for non-compliance). A monitoring infrastructure, such as meter 130 and sensors 155 verifies performance in real time to detect contingency triggers and validate that mitigation occurred as required. These systems may include dashboards, alerting interfaces, automatic disconnect, and blockchain-based enforcement mechanisms (e.g., smart contracts).

Finally, computer device 105 further supports NERC P3/P6 scenarios-a single contingency followed by another single contingency (i.e., N-1-1). Mitigation resources such as batteries 175 or flexible loads (e.g., GETs) are placed in standby mode after the first fault and activated only if a second fault occurs within a defined window. The optimization accounts for this staged logic by associating mitigation costs only with contingency activation, and response plans include logic for conditional actuation.

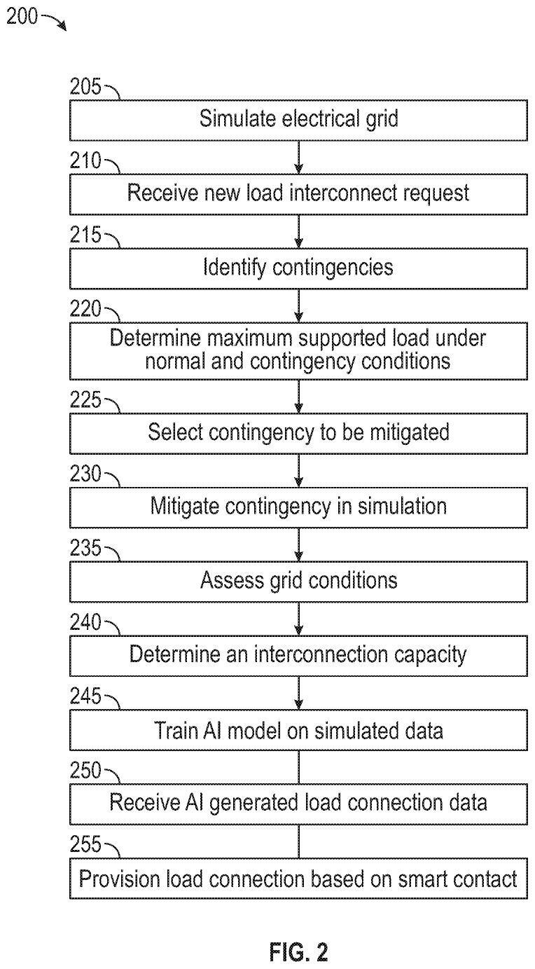

FIG. 2 illustrates an exemplary method 200 for optimizing load interconnection capacity and selective contingency mitigation. Method 200 starts with computer device 105, shown in FIG. 1, for example, simulating an electrical grid at step 205. The simulated electrical grid may be representative of a power grid operated by a particular entity or jurisdiction which may be digitally manipulated (e.g., simulated) for testing, and load connection analysis. At step 210, computer device 105 may receive a new load interconnect request through user interface 135, for example, or by access from a networked computer device, server device, cloud device, or the Internet. At step 215, computer device 105 may identify one or more contingencies associated with the new load interconnect request. Contingencies may be one or more restriction on total electrical draw or electrical draw at a certain time based on the interconnect request set forth in step 210. At step 220, computer device 105 may determine a maximum supported load under normal and contingency conditions to determine whether or not the power grid can accommodate the new interconnect request (e.g., the electrical load associated with the new interconnect request). In a normal scenario, computer device 105 determines whether or not the requested load burden can be satisfied by the electrical capacity of the power grid under normal conditions. Computer device 105 further determines whether or not the load can be supported under normal conditions with contingency offsets. In other words, computer device 105 may determine that a load for a new interconnect request could be accommodated if the load was minimized between 2:00 and 5:00 pm in the months of June-August or if the load could always be accommodated if the power grid was supplemented by one or more GETs.

At step 225, computer device 105 may select a contingency to be mitigated from the contingencies identified in step 215. For example, computer device 105 may identify the contingency that load 1 145 in FIG. 1, is a data center for which capacity is available except between 2:00 pm and 5:00 pm in the months of June-August and select that as a contingency which is to be mitigated.

Computer device 105 may apply a contingency at step 230 to the simulation to reduce the electrical demand of load 1, 145, in this example, between 2:00 pm and 5:00 pm in the months of June-August and determine at step 235 whether or not such mitigation would keep the electrical demand on grid power 140, shown in FIG. 1, under total capacity based on an assessment of power grid conditions.

At step 240, computer device 105 may determine an interconnection capacity for the power grid, which may or may not be performed as part of assessing grid conditions in step 235, to determine how much unused capacity is available on the power grid across a yearly, seasonal, monthly, weekly, daily, or hourly schedule. Computer device 105 may employ artificial intelligence engine 125 at step 245 to use the simulation data to train an artificial intelligence model with the simulated data. The model may be used for subsequent interconnection requests or may be used to provision new load requests. At step 255, an interconnect request may be provisioned as a load connection based on an agreement between the load requestor and the power grid provider to the contingencies and mitigations identified by computer device 105 based on a smart contract. Computer device 105 may then monitor load 1 145, for example, through sensors 155 to manage compliance as previously discussed.

In some cases, identifying a contingency may be based on mathematical optimizations and probabilities. For example, the method for the monitoring system includes a mathematical formulation where each contingency s∈S has a known probability pₛ, duration dₛ, and maximum mitigation potential ⁻rₛ that corresponds for example to the maximum load reduction available under the scenario. The optimization model identifies a binary mitigation decision xₛ and continuous mitigation magnitude rₛ for each scenario. The objective function minimizes total cost, including energy cost, risk-weight, and duration-adjusted penalties, subject to ensuring that for all unmitigated contingencies, the system remains within limits. The problem can be expressed as a Mixed-Integer Linear Program (MILP) or as a two-stage stochastic program. The stochastic version accounts for the uncertainty in which contingencies occur and dynamically adjusts the mitigation dispatch as needed.

In one embodiment, the optimization computation time is reduced through machine learning-based acceleration. A physics-informed neural network is trained on historical contingency simulations, wherein the network architecture incorporates power flow equations as soft constraints in the loss function.

The training data comprises historical contingency simulation results from the grid planning database, with input features including transmission line thermal ratings, bus voltage magnitudes and angles, generation dispatch levels, and load profiles at each bus. In one example, a generative artificial intelligence model may be trained on historical contingency simulations and real-world solutions and physics-informed neural networks incorporating power flow equations as constraints. The output of the trained network is an initial feasible solution vector for the mitigation decision variables. The trained network provides warm-start solutions to the MILP solver, reducing the solver's search space and computation time. Alternative acceleration approaches include GPU-accelerated and parallelized contingency screening, wherein multiple contingency scenarios are evaluated simultaneously, and generative models trained to propose candidate mitigation strategies based on learned patterns from historical interconnection studies. Other machine-based models may be provided by a generative artificial intelligence system to reduce the combinatorial search space for an N-k contingency selection, where k identifies on or more of a NERC standard, such as P0-P7 by a single number 1-7. A generative artificial intelligence model may use the foregoing data or techniques to generate scenarios or real-world solutions to satisfy contingency requirements for connecting a new load to a power grid.

Computer device 105 computes a predictive interconnection cost estimate C_total using the following methodology:

C_total=C_capital+C_operational+C_risk+C_comparison
Where: (1) Capital Cost Component (C_capital) is:
C_capital=Σ(x_s×K_s) for all s∈S_mitigated
where x_s is the binary mitigation decision variable, K_s is the capital cost for mitigation infrastructure required for contingency s, comprising battery storage systems at $/kW installed capacity rates; backup generation at $/kW capacity rates; FACTS device installation costs; and grid-forming inverter costs. Capital costs are annualized using a weighted average cost of capital (WACC) over the expected asset lifetime.

The Operational Cost Component (C_operational) is:

C_operational=Σ(p_s×d_s×r_s×c_dispatch)×T
where p_s is the probability of contingency s occurring, d_s is the expected duration in hours, r_s is the mitigation magnitude in MW, c_dispatch is the per-MWh dispatch cost for the mitigation resource, and T is the contract term in years. For battery storage, c_dispatch includes degradation costs; for backup generation, c_dispatch includes fuel costs and startup costs.

The Probability-Weighted Risk Cost (C_risk) is
C_risk=2 (p_s×VOLL×ENS_s) for all s∈S_unmitigated
where VOLL is the Value of Lost Load ($/MWh) representing the economic cost of unserved energy, and ENS_s is the Expected Not Served energy for unmitigated contingency s. This component quantifies the residual risk accepted by the load customer.

The Comparison Against Traditional Upgrades (C_comparison) is
the cost (estimated or historical) of traditional network upgrades (C_traditional) that would be required to serve the same interconnection capacity without mitigation, including transmission line construction or reconductoring; substation upgrades; transformer additions. The cost comparison ratio R=C_total/C_traditional is computed and presented to the load facility operator.

The Sensitivity Analysis is
varying key parameters (contingency probabilities, fuel costs, WACC) within defined ranges and presenting a cost range [C_min, C_max] with confidence intervals.

Computer device 105 supports the definition of risk-informed thresholds, such as the cumulative probability of unmitigated scenarios must be below a specified threshold; mitigation must be available only during certain hours or seasons; and response obligations vary dynamically based on forecasted system risk or congestion levels. This allows the interconnection process to align with actual operating risk and avoid overly conservative constraints limiting more utilization of existing capacity.

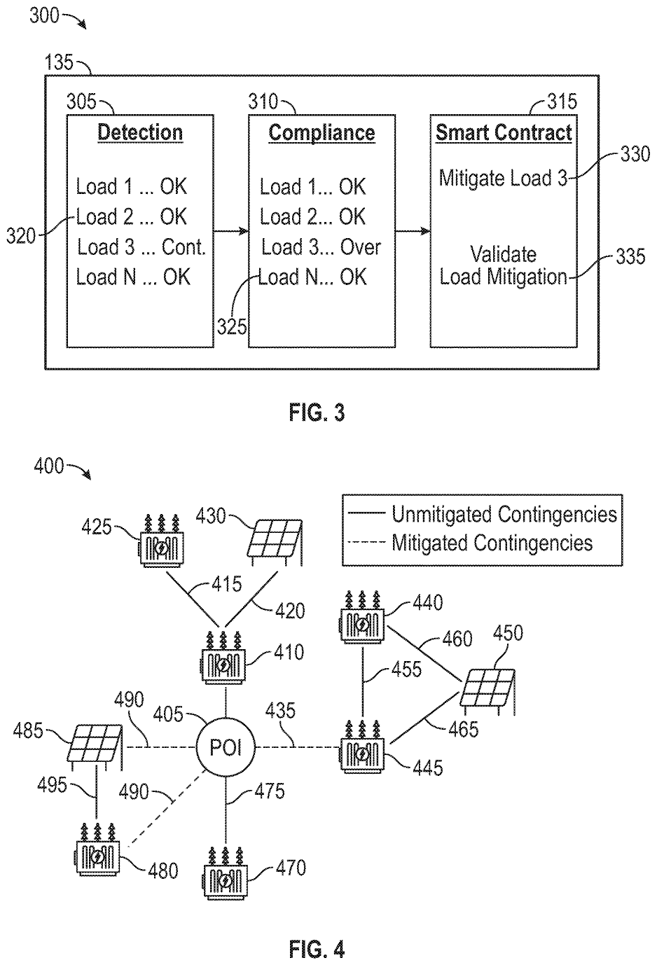

FIG. 3 illustrates an exemplary user interface 300 for a power system which experiences optimization of load interconnection capacity and selective contingency mitigation. User interface 300 may be displayed on a screen associated with computer device 105, shown in FIG. 1. User interface 300 may be provided by a user interface module 135 within computer device 105, as shown in FIG. 1. As shown in FIG. 3, user interface 300 includes a detection portion 305, a compliance portion 310, and a smart contract portion 315. Detection portion may be an alerting interface which may notify one or more users of computer device 105 or users of other networked devices that a contingency has been triggered. As shown in detection portion 305, one of many loads 320, called load 3 is identified as having entered a contingency phase. The detection portion 305 can also allow a user to specify preferences and constraints for system 100. Compliance portion 310 may provide a notification to load requestors, or load users, identifying one of many loads 325, called load 3 that is over-drawn for its agreed on capacity. As shown in FIG. 3, compliance portion 310 shows load 3 is out of compliance and over-drawn which means that load 3 is using more electricity from grid power 140, shown in FIG. 1, than is provisioned for load 3. Smart contract portion 315 may invoke terms of a smart contract and display a determine mitigations element 330 for load 3 and validate that load mitigations have occurred at element 335. User interface 300 may be provided to both the power grid provider (the utility) and to an administrator of system 100, computer device 105, and to the user (the load requestor).

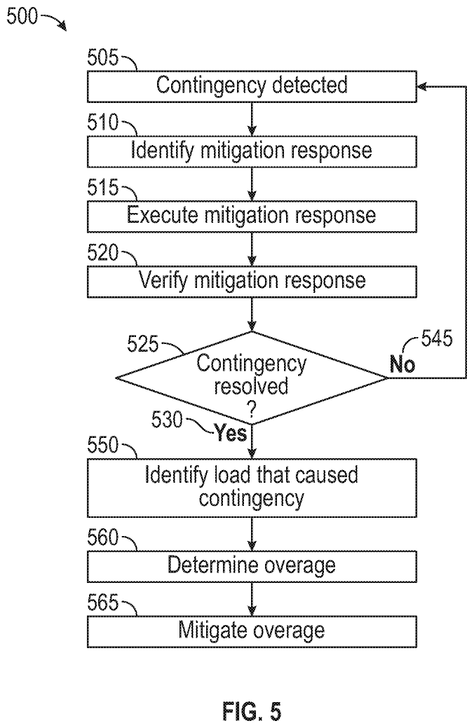

FIG. 4 illustrates an exemplary view of a power system 400 with mitigated and unmitigated power system contingencies. As shown in FIG. 5, a new POI is requested for provisioning. Either in a simulation provided by computer device 105 or in actually provisioning a new electrical load by computer device 105, computer device 105 may identified as mitigated and unmitigated contingencies. For example, in the embodiment shown in FIG. 4, a new POI 405 is provisioned or simulated. POI 405 includes unmitigated contingencies 410 and 475 which are connections to nearby substations, generators, and lines where at least some of the contingencies are selected for mitigation. Other mitigated contingencies are illustrated as unmitigated contingencies 435 and 490 for POI 405. Substation 410 may further e connected to mitigated contingencies 415 to another substation 425 and a solar array 430. Substation 445 may be connected in an unmitigated contingency to another substation 440, a solar array 450 by an unmitigated contingency connection 460, which may be, in turn, connected by an unmitigated contingency connection 465 back to substation 445. POI 405 may further be connected to mitigated contingencies 490 to substation 480 and solar array 485 where solar array 485 and substation 480 are connected as unmitigated contingencies. In sum, FIG. 4 shows an architecture for a particular grid scenario where various elements in the system are designated as mitigated or unmitigated contingencies at any point by computer device 105.

FIG. 5 illustrates a method 500 for mitigating a contingency. As shown in FIG. 5, a contingency is detected at step 505 by computing device 105 which may be a condition in a power grid that exceeds a prior parameter setting based on mutual agreement from both the utility provider and the load requestor. Typical contingencies may be around total electrical draw capacity and timing of electrical draw, as previously discussed. At step 510, computing device 510 may identify a mitigation response based on GET assets available to the grid power in terms of secondary power availability from alternative power generating assets. After an agreed to contingency time, computing device 105 may execute a mitigation response by load shedding, backup power generation, energy storage, or GETs using any techniques described herein or known in the art to resolve the contingency. Computing device, at step 520, may verify the mitigation response has been applied and detect through meter 130 and sensors 155 whether or not the contingency is resolved at step 525. If the contingency is not resolved at step 545 (No), the method returns to step 505 to identify another mitigation response. If the contingency is resolved at step 530 (yes), computing device 105 identifies the load that caused the contingency at step 550, determines the overage or the contractual provisions and consequences for the overage at step S650, and mitigates the overage at step 565 by informing the load requestor of the contractual consequences caused by the contingency condition detected in step 505.

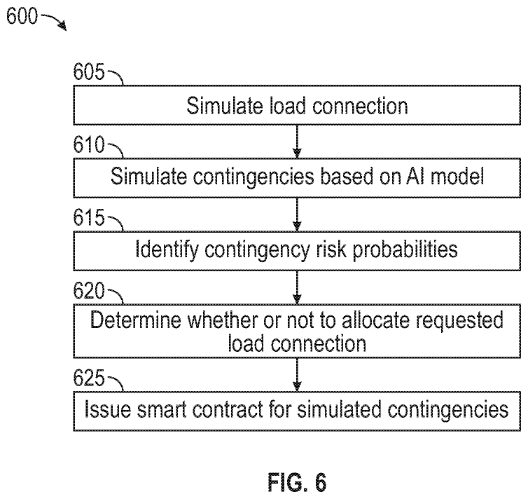

FIG. 6 illustrates a method 600 for simulating a load connection and analyzing risk probabilities. Method 600 beings at step 605 by simulating a load connection by computer device 105. At step 610, computer device 105 simulates contingencies for the load connection of step 605 based on an artificial intelligence model which is trained based on historical data for the particular power grid from which the load connection is requested. At step 615, computer device 105 may identify contingency risk probabilities based on a basic optimization model for selective contingency mitigation. In one example the probabilities may be determined as follows:

Let:
S: Set of contingency scenarios, indexed by s
pₛ: Probability of contingency s∈S
dₛ: Median duration (in hours) of contingency s
rₛ: Power reduction (in MW) required to mitigate contingency s
Cₛ: Available capacity (in MW) under contingency s without mitigation
L: Desired load to be interconnected at the Point of Interconnection (POI)
xₛ∈{0,1}: Binary decision variable; xₛ=1 if contingency s is mitigated, xₛ=0 otherwise The optimization problem is formulated as:
Minimize: X
   xₛ·f(rₛ, pₛ, dₛ)
   s∈S
Subject Cₛ+xₛ·rₛ≥L ∀s∈:
to:
   xₛ∈{0,1}∀s∈S
where f (rₛ, pₛ, dₛ) is a user-defined cost function that may take the form:

f(rₛ, pₛ, dₛ)=α·rₛ+β·pₛ+γ·dₛ+dₛ++rₛpₛdₛ

This optimization minimizes the weighted or composite cost of mitigating selected contingencies. The constraint ensures that under any unmitigated contingency (i.e., where xₛ=0), the remaining capacity Cₛ must be sufficient to support the full load L. Further, the cost function is flexible and can be adapted to incorporate economic, reliability, or regulatory priorities.

In another optimization, a two-stage stochastic optimization may be performed where first stage decisions are based on a pre-commitment of which contingencies to mitigate (xₛ) and a second stage resource with scenario-dependent adjustments

$$( {r}_{s}^{ω} ) ,$$

load-shedding, storage, or curtailment. The optimization can then be formulated as a two-stage stochastic program as follows:
Minimize expected cost:

min^{X}πₛ·Qₛ(xₛ)×s∈S
where

$${Q}_{s} ( {x}_{s} ) = {min}_{{r}_{s}^{ω}} \{ α \cdot {r}_{s}^{ω} + penalty terms \vert {C}_{s} + {r}_{s}^{ω} \geq L , {r}_{s}^{ω} \leq {\ddot{r}}_{s} \cdot {x}_{s} \}$$

At step 620, based on the probabilities of a contingency risk, computer device 105 may determine whether or not to allocate a requested load connection. In the case computer device 105 determines that the load connection should be provisioned, computer device 105 issues smart contract parameters for the simulated contingencies.

Various examples of systems and methods described herein are provided below.

Hourly Assessment Example: A data center requests interconnection at a POI in a region with solar-driven load patterns. The grid operator identifies a subset of N-1 transmission contingencies that only become binding during afternoon peak (2-6 PM). The optimization selects mitigation for these contingencies during those hours using dispatchable storage, while no mitigation is required during nighttime hours.

Seasonal Assessment Example: A 150 MW industrial load seeks connection in a mountainous area prone to winter transmission congestion. Based on historical data, several P6 contingencies are only critical between November and March. The system selects mitigation measures—including partial load reduction and backup diesel generation—only for the winter period, allowing full capacity in other months.

Combined Hourly and Seasonal Example: A hydrogen electrolyzer is proposed for a wind-rich area. The optimization process determines that specific contingencies require mitigation only on winter nights, when wind output is high and load is low, potentially leading to overvoltages. The mitigation contract activates battery-based voltage support only during these windows, minimizing year-round operational costs.

Probability-Weighted Selection Example: Among 60 identified contingencies, 10 have historically occurred with high frequency due to substation hardware vulnerabilities. The system prioritizes these for mitigation, even though their technical severity is moderate, by optimizing a weighted objective that accounts for both probability and load impact.

Dynamic Adjustment Example: During wildfire season, the probability of outages on specific transmission corridors increases significantly. The system dynamically adjusts the subset of contingencies requiring mitigation based on near real-time risk inputs, using satellite derived weather and vegetation models.

Subexample 2: Contingency Selection Based on Load Reduction and Probability A proposed interconnection for a 120 MW crypto mining facility is evaluated across 35 contingencies. Using historical fault logs, the optimization algorithm prioritizes for mitigation those contingencies that both: (i) require low levels of load curtailment (below 8 MW), and (ii) have a historical annual occurrence probability above 0.5%. These are selected for mitigation while more severe, less probable scenarios are left unmitigated.

Subexample 3: Multi-Objective Optimization A transmission-constrained valley receives a new industrial load interconnection request. The system operator configures an objective function that includes: —Minimizing total annual mitigation cost, —Minimizing operational disruption (measured in MWh curtailed), and —Accounting for probability of each contingency. The optimization engine solves this as a weighted multi-objective problem and selects a compromise mitigation plan balancing these priorities.

Subexample 4: Precomputed Contingency Ranking A utility integrates a ranking system for contingencies based on a hybrid score:

Score=0.6×Historical Frequency+0.4×Technical Severity

When a new interconnection request is made, the 15 top-ranked contingencies are automatically pulled for mitigation planning, streamlining the review process and aligning with system planning practice.

Subexample 5: Probability Constraint on Unmitigated Risk A data center interconnection project accepts a reliability constraint requiring the cumulative probability of unmitigated contingencies to be below 2%. The optimization selects a subset of 20 contingencies to mitigate, leaving 10 unmitigated, but their total probability is 1.3%. The planning objective is met while minimizing cost.

Subexample 6: MILP-Based Optimization A vertically integrated utility implements the mitigation optimization model using a Mixed-Integer Linear Program (MILP). Decision variables represent binary mitigation flags and continuous mitigation magnitudes. The MILP framework ensures scalability and compatibility with legacy grid planning software.

Subexample 7: Greedy Selection Algorithm In a real-time operation setting, a greedy heuristic is applied instead of MILP. Contingencies are ranked by severity, and mitigation resources are allocated iteratively to the most impactful ones until the interconnection constraint is satisfied.

Subexample 8: Probabilistic Threshold-Based Selection The utility applies a rule that total risk exposure (sum of probabilities for all unmitigated contingencies) must be less than 5%. This enables risk-informed planning and facilitates dynamic updates as new reliability data becomes available.

Subexample 9: Fast-Response Energy Storage A battery co-located at a commercial load site is used to mitigate voltage dips triggered by local P2 contingencies. The storage system is configured to inject 5 MW within 1 second of detection, satisfying mitigation obligations with minimal disruption.

Subexample 10: Grid Enhancing Technology Use Dynamic line ratings (DLR) are used to increase transmission line capacity during cooler nighttime hours. This GET allows avoidance of load curtailment during a P3 contingency that would otherwise require partial disconnection of a data center.

Subexample 11: User-Defined Cost Function An industrial user submits a customized cost function that penalizes frequent load drops more than storage dispatch. The optimization adapts by shifting mitigation preference toward battery usage.

Subexample 12: Use of Historical Data The mitigation strategy is validated using SCADA archive data from the last 3 years. Past event frequencies are used to filter low-risk contingencies from the candidate mitigation set.

Subexample 13: Timely Mitigation Actions The system enforces a 10-second window for initiating mitigation after contingency detection. Batteries and fast-ramping backup generators are pre-armed to meet this requirement.

Subexample 14: Temporal Coordination A peaking load site has mitigation scheduled only from 4:30 PM to 8 PM daily. Outside this window, no action is required, minimizing resource wear and cost.

Subexample 15: Forecast-Informed Updates Seasonal load forecast data is used to revise the set of contingencies that require mitigation. Contingencies impacting summer peak flows are included in July but removed in October.

Subexample 16: Economic Feasibility Constraints The optimization excludes mitigation plans that would result in market penalties or violate demand response program limits, ensuring both technical feasibility and market compatibility.

Subexample 17: Weighted Likelihood Selection The optimization model weights contingencies by a score combining severity and expected frequency. A contingency with 5% probability and high disruption is mitigated before one with 0.1% probability and moderate impact.

Subexample 18: Probabilistic Interconnection Assessment Using Monte Carlo simulations, the planner computes a 95% confidence level for the proposed interconnection capacity based on simulated contingency events and dispatch availability.

Other illustrative applications include Interconnecting data centers that can reduce or shift load for selected hours, industrial sites with on-site generation or backup batteries capable of responding to grid events, renewable energy projects coordinating mitigation (e.g., renewables co-located with load projects) based on wind or solar forecasts, and hydrogen electrolyzers with dispatchable profiles based on marginal grid congestion cost.

Other embodiments may include use of probabilistic risk-based contingency assessment; seasonal or time-varying contingency mitigation contracts; integration of renewable forecasts into the mitigation plan; contingency prioritization based on a hybrid of technical severity and occurrence likelihood; machine learning-based prediction of future contingency relevance; and machine learning-based warm-starting of optimization solvers using physics-informed neural networks trained on historical simulations.

These systems and methods provide advantages which include increased load interconnection capacity without expensive and long lead time network upgrades, reduce cost, accelerate interconnection timelines, enables use of modern flexible technologies, and are compatible with jurisdictional requirements, including existing NERC reliability frameworks.

The foregoing description has been presented for purposes of illustration. It is not exhaustive and does not limit the invention to the precise forms or embodiments disclosed. Modifications and adaptations will be apparent to those skilled in the art from consideration of the specification and practice of the disclosed embodiments. For example, components described herein may be removed and other components added without departing from the scope or spirit of the embodiments disclosed herein or the appended claims.

Other embodiments will be apparent to those skilled in the art from consideration of the specification and practice of the disclosure disclosed herein. It is intended that the specification and examples be considered as exemplary only, with a true scope and spirit of the invention being indicated by the following claims.

What is claimed is:

1. A method for determining the maximum load capacity that can be interconnected to an electrical grid at a Point of Interconnection (POI), the method comprising:
simulating an electrical grid
receiving a capacity request for interconnecting a load at the POI;
identifying a set of contingency scenarios, including but not limited to NERC defined N-1 and N-1-1 contingencies;
determining, for each contingency scenario, a maximum supported load at the POI under normal and contingency conditions;
selecting a subset of contingency scenarios to be mitigated based on an optimization criterion;
applying one or more mitigation strategies under the selected contingency scenarios, the mitigation strategies comprising at least one of:
load reduction at the POI,
dispatch of local or co-located energy storage systems,
activation of backup generation resources,
deployment or adjustment of grid-enhancing technologies;
performing assessments on an hourly, seasonal, or combined hourly and seasonal basis to account for variations in grid conditions and contingency risks;
and determining, based on one or more parameters, an interconnection capacity that satisfies operational criteria under non-mitigated contingencies and mitigated performance under the selected contingencies.

2. The method of claim 1, wherein the subset of contingencies is selected based on at least one of: expected total load reduction, probability of occurrence, operational cost, or combinations thereof.

3. The method of claim 1, wherein the optimization criterion includes a weighted multi-objective function that balances total expected mitigation cost, probability of contingency occurrence, environmental impact, critical load priority, and operational disruption.

4. The method of claim 1, wherein selection of contingency scenarios is based on a precomputed ranking of contingencies using historical failure data or predictive analytics.

5. The method of claim 1, wherein the optimization includes constraints to ensure the total cumulative probability of unmitigated contingencies remains below a defined threshold.

6. The method of claim 1, wherein the optimization criterion is formulated as a mixed-integer linear program (MILP) or other mathematical programming model.

7. The method of claim 6, wherein the optimization is accelerated using one or more of: generative artificial intelligence models trained on historical contingency solutions; physics-informed neural networks incorporating power flow equations as constraints; GPU-accelerated parallel solvers; or machine learning-based heuristics that reduce the combinatorial search space for N-k contingency selection.

8. The method of claim 1, wherein the optimization criterion is met by utilizing a greedy selection algorithm.

9. The method of claim 1, wherein the subset of contingencies is selected to meet a probabilistic reliability threshold.

10. The method of claim 1, wherein energy storage is co-located and used to inject power within a pre-defined response time.

11. The method of claim 1, wherein grid-enhancing technologies comprise at least one of: FACTS devices including Static VAR Compensators (SVCs), Static Synchronous Compensators (STATCOMs), and Thyristor-Controlled Phase-Shifting Transformers (TCPSTs); Dynamic Line Rating (DLR) systems; Topology Optimization controllers; and Grid-Forming Inverters capable of providing synthetic inertia and voltage support during contingency events.

12. The method of claim 1, further comprising receiving a user-defined cost function and selecting mitigation strategies to minimize cost.

13. The method of claim 1, further comprising using real-time or historical data to assess system impact.

14. The method of claim 1, wherein mitigation actions occur within a defined time window.

15. The method of claim 1, wherein the mitigation strategies are temporally coordinated to occur within a specified response time window after contingency detection.

16. The method of claim 1, wherein the subset of contingencies is updated based on forecasted congestion or seasonal conditions.

17. The method of claim 1, wherein mitigation is constrained by economic feasibility or market participation rules.

18. The method of claim 1, wherein a weighted likelihood is used to guide contingency mitigation.

19. The method of claim 1, wherein the determination of interconnection capacity includes probabilistic assessment of contingency likelihoods, and weighted mitigation is applied accordingly.

20. The method of claim 1, wherein multiple POIs are considered simultaneously for multiple load requests and contingency mitigation is selected by jointly optimizing the options of the multiple POIs, and reductions are assigned by taking into account a cost of reduction for each load.
